(19) United States
(12) Patent Application Publication
(10) Pub. No.: US 2020/0243353 A1
(43) Pub. Date: Jul. 30, 2020

(54) CONTROL METHOD OF HEAT MEDIUM AND HEAT MEDIUM CONTROL APPARATUS

(71) Applicant: Tokyo Electron Limited, Tokyo (JP)

(72) Inventors: Kei Kobayashi, Kurokawa-gun (JP); Takehiko Arita, Kurokawa-gun (JP)

(21) Appl. No.: 16/750,189

(22) Filed: Jan. 23, 2020

(30) Foreign Application Priority Data
Jan. 25, 2019 (JP) 2019-011571

(51) Int. Cl. H01L 21/67; H01J 37/32; H01L 21/3065; H01L 21/683; H01L 21/687

(52) U.S. Cl. CPC H01L 21/67098; H01J 37/32724; H01L 21/68714; H01L 21/67248; H01L 21/6833; H01L 21/3065

(57) ABSTRACT

A control method of a heat medium includes a flow rate control process and a supply stop process. In the flow rate control process, a flow rate of the heat medium is decreased in a state where the heat medium is being supplied from a temperature controller configured to supply the heat medium whose temperature is controlled into a flow path formed in a heat exchange member configured to exchange heat with a temperature control target object. In the supply stop process, a supply of the heat medium into the flow path is stopped by controlling a supply valve provided at a supply line that connects the temperature controller and the flow path of the heat exchange member.

### CROSS-REFERENCE TO RELATED APPLICATION

This application claims the benefit of Japanese Patent Application No. 2019-011571 filed on Jan. 25, 2019, the entire disclosure of which is incorporated herein by reference.

### TECHNICAL FIELD

The exemplary embodiments described herein pertain generally to a control method of a heat medium.

### BACKGROUND

For example, Patent Document 1 discloses a recirculation system which can rapidly change a substrate temperature by circulating a temperature controlled liquid through a flow path provided in a substrate support on which a substrate to be processed in a plasma chamber is placed. This recirculation system is equipped with two (e.g., cold liquid and hot liquid) recirculators, and one of the recirculators is used as a pre-charge heating unit and the other one is used as a pre-charge cooling unit.

Patent Document 1: Published Japanese Translation of PCT Patent Application No. 2013-534716

### SUMMARY

In one exemplary embodiment, a control method of a heat medium includes a flow rate control process and a supply stop process. In the flow rate control process, a flow rate of the heat medium is decreased in a state where the heat medium is being supplied from a temperature controller configured to supply the heat medium whose temperature is controlled into a flow path formed in a heat exchange member configured to exchange heat with a temperature control target object. In the supply stop process, a supply of the heat medium into the flow path is stopped by controlling a supply valve provided at a supply line that connects the temperature controller and the flow path of the heat exchange member.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

In the detailed description that follows, exemplary embodiments are described as illustrations only since various changes and modifications will become apparent to those skilled in the art from the following detailed description. The use of the same reference numbers in different figures indicates similar or identical items.

FIG. 1 is a schematic configuration view illustrating an example of a plasma processing apparatus according to an exemplary embodiment of the present disclosure;

FIG. 2 is a diagram illustrating an example of a temperature control device according to a first exemplary embodiment of the present disclosure;

FIG. 3 is a timing chart showing an example of an operation of the temperature control device according to the first exemplary embodiment of the present disclosure;

FIG. 4 is a diagram illustrating an example of the temperature control device in an initial state;

FIG. 5 is a diagram illustrating an example of the temperature control device in a state that a first bypass valve is opened;

FIG. 6 is a diagram illustrating an example of the temperature control device in a state that a first supply valve is closed;

FIG. 7 is a diagram illustrating an example of a variation in pressure applied to the first supply valve when the flow of a first heat medium is blocked;

FIG. 8 is a diagram illustrating an example of the temperature control device in a state that a second supply valve is opened;

FIG. 9 is a diagram illustrating an example of the temperature control device in a state that a second return valve is opened;

FIG. 10 is a diagram illustrating an example of the temperature control device in a state that a first return valve is closed;

FIG. 11 is a diagram illustrating an example of the temperature control device in a state that a second bypass valve is closed;

FIG. 12 is a flowchart showing an example of a control method of a heat medium according to the first exemplary embodiment of the present disclosure;

FIG. 13 is a timing chart showing an example of a control method of a heat medium according to a second exemplary embodiment of the present disclosure;

FIG. 14 is a diagram illustrating an example of a temperature control device according to a third exemplary embodiment of the present disclosure; and

FIG. 15 is a flowchart showing an example of a control method of a heat medium according to the third exemplary embodiment of the present disclosure.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other exemplary embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments of a control method of a heat medium and a heat medium control apparatus will be described in detail with reference to the accompanying drawings. The control method of the heat medium and the heat medium control apparatus of the present disclosure are not limited to the following exemplary embodiments.

When a set temperature of a temperature control object is changed, a heat medium flowing in a flow path of a heat exchange member configured to exchange heat with the temperature control object is switched with another heat medium of a different temperature. In this case, the supply of the heat medium supplied to the heat exchange member is stopped and the supply of the another heat medium is started.

When a valve provided in the flow path for the heat medium is closed to stop the supply of the heat medium, inertial force of the heat medium applies a pressure, called water hammer, to the valve. If the pressure of the water hammer applied to the valve is high, the valve may be broken, and, thus, the heat medium may leak or flow backward. For this reason, the use of a valve having high pressure resistance has been considered. However, it is difficult to miniaturize and lighten the valve having high pressure resistance. For this reason, an apparatus for controlling a heat medium has become bigger and heavier, and thus can be difficult to handle.

Accordingly, the present disclosure provides a technology capable of suppressing the water hammer associated with the stop of supply of the heat medium.

### First Exemplary Embodiment

[Configuration of Plasma Processing Apparatus 1]

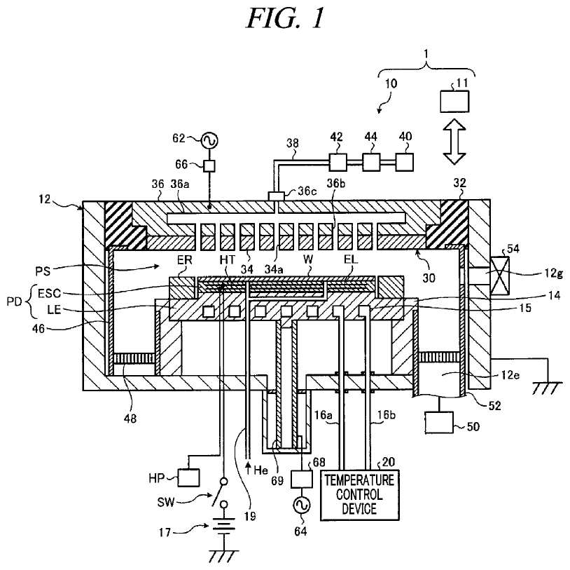

FIG. 1 is a schematic configuration view illustrating an example of a plasma processing apparatus 1 according to an exemplary embodiment of the present disclosure. In the present exemplary embodiment, the plasma processing apparatus 1 is configured as, e.g., a plasma etching apparatus having parallel plate type electrodes. The plasma processing apparatus 1 is equipped with an apparatus main body 10 and a control device 11. The apparatus main body 10 includes a processing vessel 12 made of, e.g., aluminum or the like and having, e.g., a substantially cylindrical shape. The processing vessel 12 has an inner wall surface that is anodically oxidized. Further, the processing vessel 12 is frame-grounded.

A substantially cylindrical support 14 made of an insulating material such as quartz or the like is provided on a bottom portion of the processing vessel 12. Within the processing vessel 12, the support 14 extends in a vertical direction (e.g., toward an upper electrode 30) from the bottom portion of the processing vessel 12.

A mounting table PD is provided within the processing vessel 12. The mounting table PD is supported by the support 14. The mounting table PD is configured to hold a wafer W on a top surface thereof. The wafer W is an example of a temperature control object. The mounting table PD includes an electrostatic chuck ESC and a lower electrode LE. The lower electrode LE is made of a metal material such as aluminum or the like and has a substantially disk shape. The electrostatic chuck ESC is placed on the lower electrode LE. The lower electrode LE is an example of a heat exchange member configured to exchange heat with the temperature control object.

The electrostatic chuck ESC has a structure in which an electrode EL as a conductive film is embedded between a pair of insulating layers or a pair of insulating sheets. A DC power supply 17 is electrically connected to the electrode EL. The electrostatic chuck ESC attracts the wafer W onto the top surface thereof by an electrostatic force such as a Coulomb force generated by a DC voltage supplied from the DC power supply 17. Accordingly, the electrostatic chuck ESC can hold the wafer W.

The electrostatic chuck ESC is supplied with a heat transfer gas such as a He gas through a line 19. The heat transfer gas supplied through the line 19 is supplied between the electrostatic chuck ESC and the wafer W. By controlling a pressure of the heat transfer gas to be supplied between the electrostatic chuck ESC and the wafer W, thermal conductivity between the electrostatic chuck ESC and the wafer W can be controlled.

Within the electrostatic chuck ESC, a heater HT serving as a heating device is also provided. The heater HT is connected to a heater power supply HP. Since a power is supplied to the heater HT from the heater power supply HP, the wafer W on the electrostatic chuck ESC can be heated via the electrostatic chuck ESC. The temperature of the wafer W placed on the electrostatic chuck ESC is controlled by the lower electrode LE and the heater HT. The heater HT may be provided between the electrostatic chuck ESC and the lower electrode LE.

An edge ring ER is provided around the electrostatic chuck ESC to surround the edge of the wafer W and the electrostatic chuck ESC. The edge ring ER may also be referred to as a focus ring. The edge ring ER is provided to improve the processing uniformity of the wafer W. The edge ring ER is made of a material, such as quartz, appropriately selected by a material of a film to be etched.

Within the lower electrode LE, a flow path 15 in which a heat medium which is an insulating fluid such as Galden (registered trademark) flows is provided. The flow path 15 is connected to a temperature control device 20 via a line 16a and a line 16b. The temperature control device 20 controls the temperature of the heat medium flowing in the flow path 15 of the lower electrode LE. The heat medium whose temperature is controlled by the temperature control device 20 is supplied into the flow path 15 of the lower electrode LE through the line 16a. The heat medium that has flown in the flow path 15 is returned to the temperature control device 20 through the line 16b.

The temperature control device 20 switches between a heat medium of a first temperature and a heat medium of a second temperature, and supplies the switched heat medium into the flow path 15 of the lower electrode LE. By switching between the heat medium of the first temperature and the heat medium of the second temperature and supplying the switched heat medium into the flow path 15 of the lower electrode LE, the temperature of the lower electrode LE can be switched between the first temperature and the second temperature. The first temperature may be a temperature equal to or higher than, e.g., room temperature, and the second temperature may be a temperature equal to or lower than, e.g., 0° C. In the following description, the heat medium of the first temperature will be described as “first heat medium” and the heat medium of the second temperature will be described as “second heat medium”. The first heat medium and the second heat medium are different from each other in temperature, but both are fluids made of the same material. The temperature control device 20 and the control device 11 are an example of a heat medium control apparatus.

A bottom surface of the lower electrode LE is electrically connected to a power feed line 69 configured to supply a high frequency power to the lower electrode LE. The power feed line 69 is made of a metal. Although not illustrated in FIG. 1, lifter pins configured to deliver the wafer W on the electrostatic chuck ESC and a driving mechanism therefor are placed in a space between the lower electrode LE and the bottom portion of the processing vessel 12.

The power feed line 69 is connected to a first high frequency power supply 64 via a matching device 68. The first high frequency power supply 64 is a power supply configured to generate high frequency power, i.e., high frequency bias power, for attracting ions to the wafer W, and generates a high frequency bias power having a frequency within a range of from 400 kHz to 40.68 MHz, e.g., a frequency of 13.56 MHz. The matching device 68 is a circuit configured to match an output impedance of the first high frequency power supply 64 and an input impedance at the load side (the lower electrode LE side). The high frequency bias power generated by the first high frequency power supply 64 is supplied to the lower electrode LE through the matching device 68 and the power feed line 69.

An upper electrode 30 is provided above the mounting table PD, facing the mounting table PD. The lower electrode LE and the upper electrode 30 are provided substantially parallel to each other. In a space between the upper electrode 30 and the lower electrode LE, plasma is formed. With the formed plasma, a plasma processing such as etching is performed on the wafer W held on the top surface of the electrostatic chuck ESC. The space between the upper electrode 30 and the lower electrode LE is a processing space PS.

The upper electrode 30 is supported at a top portion of the processing vessel 12 via an insulating shield member 32 made of, e.g., quartz or the like. The upper electrode 30 includes an electrode plate 34 and an electrode supporting body 36. A bottom surface of the electrode plate 34 faces the processing space PS. The electrode plate 34 has a plurality of gas discharge openings 34a. The electrode plate 34 is formed of a material containing, e.g., silicon.

The electrode supporting body 36 is made of a conductive material such as aluminum or the like, and supports the electrode plate 34 from above in a detachable manner. The electrode supporting body 36 may have a non-illustrated water-cooling structure. Within the electrode supporting body 36, a diffusion space 36a is formed. A plurality of gas through holes 36b, that respectively communicate with the gas discharge openings 34a of the electrode plate 34, extends downwards (toward the mounting table PD) from the diffusion space 36a. The electrode supporting body 36 has a gas inlet opening 36c through which a processing gas is introduced into the diffusion space 36a, and the gas inlet opening 36c is connected to a line 38.

The line 38 is connected to a gas source group 40 via a valve group 42 and a flow rate controller group 44. The gas source group 40 includes a plurality of gas sources. The valve group 42 includes a plurality of valves, and the flow rate controller group 44 includes a plurality of flow rate controllers such as mass flow controllers. Each gas source of the gas source group 40 is connected to the line 38 via a corresponding valve of the valve group 42 and a corresponding flow rate controller of the flow rate controller group 44.

Accordingly, the apparatus main body 10 may supply processing gases to the diffusion space 36a within the electrode supporting body 36 at individually controlled flow rates from one or more gas sources selected from the gas source group 40. The processing gases supplied into the diffusion space 36a are diffused within the diffusion space 36a to be supplied into the processing space PS in a shower shape through the gas through holes 36b and the gas discharge openings 34a.

The electrode supporting body 36 is connected to a second high frequency power supply 62 via a matching device 66. The second high frequency power supply 62 is a power supply configured to generate a high frequency power for plasma formation and generates a high frequency power having a frequency within a range of from 27 MHz to 100 MHz, e.g., a frequency of 60 MHz. The matching device 66 is a circuit configured to match an output impedance of the second high frequency power supply 62 and the input impedance at the load side (the upper electrode 30 side). The high frequency power generated by the second high frequency power supply 62 is supplied to the upper electrode 30 through the matching device 66. Further, the second high frequency power supply 62 may be connected to the lower electrode LE via the matching device 66.

A deposition shield 46 made of aluminum coated with Y₂O₃ or quartz is detachably provided along the inner wall surface of the processing vessel 12 and an outer side surface of the support 14. The deposition shield 46 is configured to suppress adhesion of an etching byproduct (deposit) to the processing vessel 12 and the support 14.

Near the bottom portion of the processing vessel 12 (where the support 14 is provided), a gas exhaust plate 48 made of aluminum coated with Y₂O₃ or quartz is detachably provided between the outer side wall of the support 14 and the inner wall surface of the processing vessel 12. A gas exhaust opening 12e is provided under the gas exhaust plate 48. The gas exhaust opening 12e is connected to a gas exhaust device 50 via a gas exhaust line 52.

The gas exhaust device 50 is equipped with a vacuum pump such as a turbo molecular pump and thus can decompress the space within the processing vessel 12 to a desired vacuum level. A carry-in/out opening 12g for the wafer W is provided at a side wall of the processing vessel 12, and the opening 12g can be opened or closed by a gate valve 54.

The control device 11 includes a processor, a memory and an input/output interface. The memory stores programs executed by the processor and recipes including processing conditions and the like. The processor executes a program read from the memory and controls the components of the apparatus main body 10 via the input/output interface based on the recipes stored in the memory to perform a predetermined processing such as etching or the like on the wafer W.

[Configuration of Temperature Control Device 20]

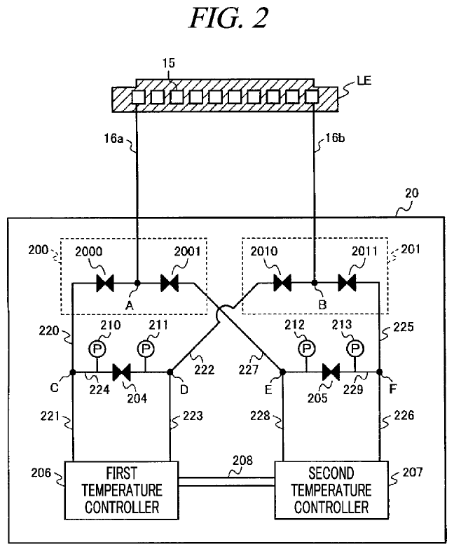

FIG. 2 is a diagram illustrating an example of a temperature control device 20 according to a first exemplary embodiment of the present disclosure. The temperature control device 20 is equipped with a first switch unit 200, a second switch unit 201, a first bypass valve 204, a second bypass valve 205, a first temperature controller 206 and a second temperature controller 207.

The first temperature controller 206 is connected to the line 16a via a line 221 and a line 220. Also, the first temperature controller 206 is connected to the line 16b via a line 223 and a line 222. In the present exemplary embodiment, the first temperature controller 206 controls the temperature of the first heat medium. The first temperature controller 206 supplies the temperature controlled first heat medium into the flow path 15 of the lower electrode LE through the line 221, the line 220 and the line 16a. The heat medium supplied into the flow path 15 of the lower electrode LE is returned to the first temperature controller 206 through the line 16b, the line 222 and the line 223. Herein, lines including the line 221, the line 220 and the line 16a are an example of a supply line or a first supply line. Also, lines including the line 16b, the line 222 and the line 223 are an example of a return line or a first return line.

The second temperature controller 207 is connected to the line 16a and the line 220 at a connection position A via a line 228 and a line 227. Further, the second temperature controller 207 is connected to the line 16b and the line 222 at a connection position B via a line 226 and a line 225. In the present exemplary embodiment, the second temperature controller 207 controls the temperature of the second heat medium. The second temperature controller 207 supplies the temperature controlled second heat medium into the flow path 15 of the lower electrode LE through the line 228, the line 227 and the line 16a. Then, the heat medium supplied into the flow path 15 of the lower electrode LE is returned to the second temperature controller 207 through the line 16b, the line 225 and the line 226. Herein, lines including the line 228 and the line 227 are an example of a second supply line. Also, lines including the line 225 and the line 226 are an example of a second return line.

The first temperature controller 206 and the second temperature controller 207 are connected to each other through a line 208. The line 208 controls liquid surfaces in a tank that stores the first heat medium within the first temperature controller 206 and a liquid surface in a tank that stores the second heat medium within the second temperature controller 207. Accordingly, it is possible to suppress the leakage of the heat medium.

The first switch unit 200 is provided at a connection portion between the line 16a and the lines 220 and 227, and switches the heat medium flowing in the flow path 15 of the lower electrode LE to the first heat medium or the second heat medium. The first switch unit 200 is equipped with a first supply valve 2000 and a second supply valve 2001. The first supply valve 2000 is an example of a supply valve.

The second switch unit 201 is provided at a connection portion between the line 16b and the lines 222 and 225, and switches the destination of the heat medium flowing out of the flow path 15 of the lower electrode LE to the first temperature controller 206 or the second temperature controller 207. The second switch unit 201 is equipped with a first return valve 2010 and the second return valve 2011. In the present exemplary embodiment, the first supply valve 2000, the second supply valve 2001, the first return valve 2010 and the second return valve 2011 are all two-way valves.

A line 224 is provided at a connection position C between the line 220 and the line 221 and at a connection position D between the line 222 and the line 223. The line 224 is an example of a bypass line. The first bypass valve 204 is provided at the line 224. A pressure gauge 210 configured to measure the pressure of the heat medium in the line 224 between the first bypass valve 204 and the connection position C is provided at the line 224 between the first bypass valve 204 and the connection position C. Also, a pressure gauge 211 configured to measure the pressure of the heat medium in the line 224 between the first bypass valve 204 and the connection position D is provided at the line 224 between the first bypass valve 204 and the connection position D.

A line 229 is provided at a connection position E between the line 227 and the line 228 and at a connection position F between the line 225 and the line 226. The second bypass valve 205 is provided at the line 229. A pressure gauge 212 configured to measure the pressure of the heat medium in the line 229 between the second bypass valve 205 and the connection position E is provided at the line 229 between the second bypass valve 205 and the connection position E. Also, a pressure gauge 213 configured to measure the pressure of the heat medium in the line 229 between the second bypass valve 205 and the connection position F is provided at the line 229 between the second bypass valve 205 and the connection position F.

Herein, opening and closing of each of the first supply valve 2000, the second supply valve 2001, the first return valve 2010, the second return valve 2011, the first bypass valve 204 and the second bypass valve 205 is controlled by the control device 11.

[Operation of Temperature Control Device 20]

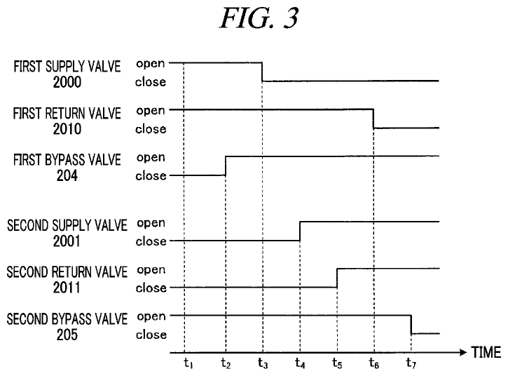

FIG. 3 is a timing chart showing an example of an operation of the temperature control device 20 according to the first exemplary embodiment of the present disclosure. The timing chart of FIG. 3 shows an operation of the temperature control device 20 in which the first heat medium flowing in the flow path 15 of the lower electrode LE is switched to the second heat medium in a state (initial state) where the first heat medium flows in the flow path 15 of the lower electrode LE. Also, a switchover from the second heat medium flowing in the flow path 15 of the lower electrode LE to the first heat medium is performed in the same order in a state where the second heat medium flows in the flow path 15 of the lower electrode LE.

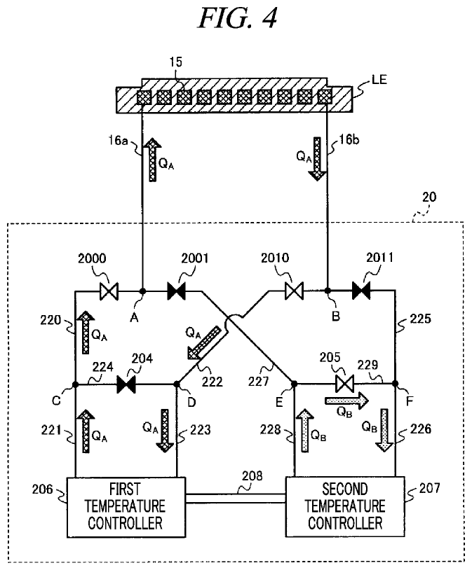

FIG. 4 is a diagram illustrating an example of the temperature control device 20 in an initial state. For example, as illustrated in FIG. 4, in the initial state, the first supply valve 2000, the first return valve 2010 and the second bypass valve 205 are opened, and the second supply valve 2001, the second return valve 2011 and the first bypass valve 204 are closed. In the following drawings, open valves are indicated in white and closed valves are indicated in black.

Accordingly, in the initial state, the first heat medium of a flow rate Q_{A} is output from the first temperature controller 206 to be supplied into the flow path 15 of the lower electrode LE through the line 221, the line 220, the first supply valve 2000 and the line 16a. Further, the first heat medium supplied into the flow path 15 of the lower electrode LE is returned to the first temperature controller 206 through the line 16b, the first return valve 2010, the line 222 and the line 223. Accordingly, the lower electrode LE is controlled to be the first temperature. Also, the second heat medium of a flow rate Q_{B} is output from the second temperature controller 207 and returned to the second temperature controller 207 through the line 228, the line 229, the second bypass valve 205 and the line 226.

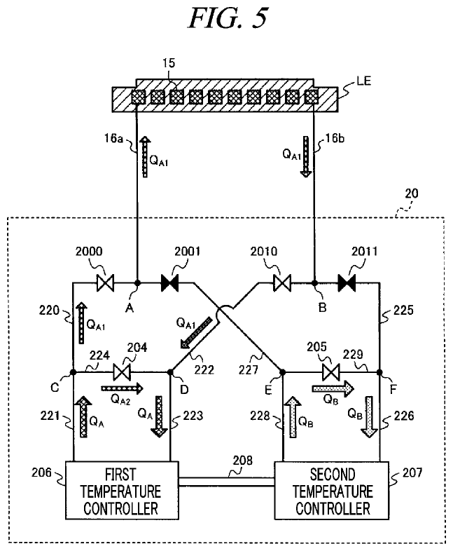

Referring to FIG. 3 again, the control device 11 detects a switchover from the first heat medium flowing in the flow path 15 of the lower electrode LE to the second heat medium at a time t₁. Then, at a time t₂, the control device 11 controls the first bypass valve 204 to open the first bypass valve 204. Accordingly, the temperature control device 20 becomes in a state, e.g., as illustrated in FIG. 5. FIG. 5 is a diagram illustrating an example of the temperature control device 20 when the first bypass valve 204 is opened.

Further, the control device 11 controls the first bypass valve 204 to be opened and then acquires measurement values of the pressure measured by the pressure gauge 210 and the pressure gauge 211. Then, the control device 11 determines whether the first bypass valve 204 is actually opened based on the acquired measurement values of the pressure. For example, when a difference between the pressure measured by the pressure gauge 210 and the pressure measured by the pressure gauge 211 is lower than a predetermined value, the control device 11 determines that the first bypass valve 204 is actually opened. For example, when the difference between the pressure measured by the pressure gauge 210 and the pressure measured by the pressure gauge 211 is equal to or higher than the predetermined value, the control device 11 determines that the first bypass valve 204 is not opened.

If it is determined that the first bypass valve 204 is not opened, the control device 11 informs a user of the plasma processing apparatus 1 about an error, and stops the switchover of the heat medium. The pressure gauge 212 and the pressure gauge 213 provided at the line 229 are used to determine a state of the second bypass valve 205 at the time of switching the second heat medium flowing in the flow path 15 of the lower electrode LE to the first heat medium. The pressure gauge 210, the pressure gauge 211, the pressure gauge 212 and the pressure gauge 213 are an example of a sensor. Further, flowmeters may be provided at the line 224 and the line 229, respectively, and whether the first bypass valve 204 and the second bypass valve 205 are actually opened may be determined based on measurement values from the flowmeters.

As the first bypass valve 204 is opened, the first heat medium of the flow rate Q_{A} output from the first temperature controller 206 is divided into the line 220 and the line 224 at the connection position C and the first heat medium of a flow rate Q_{A2} flows in the line 224. Accordingly, the first heat medium of a flow rate Q_{A1}, which is the result of subtracting the flow rate Q_{A2} from the flow rate Q_{A}, flows in the line 220. Thus, the first heat medium of the flow rate Q_{A1} is supplied into the flow path 15 of the lower electrode LE.

The first heat medium of the flow rate Q_{A1} supplied into the flow path 15 of the lower electrode LE is returned through the line 16b, the first return valve 2010 and the line 222. Further, the first heat medium of the flow rate Q_{A1} joins the first heat medium of the flow rate Q_{A2} flowing in the line 224 at the connection position D to become the first heat medium of the flow rate Q_{A}. The first heat medium of the flow rate Q_{A} is returned to the first temperature controller 206.

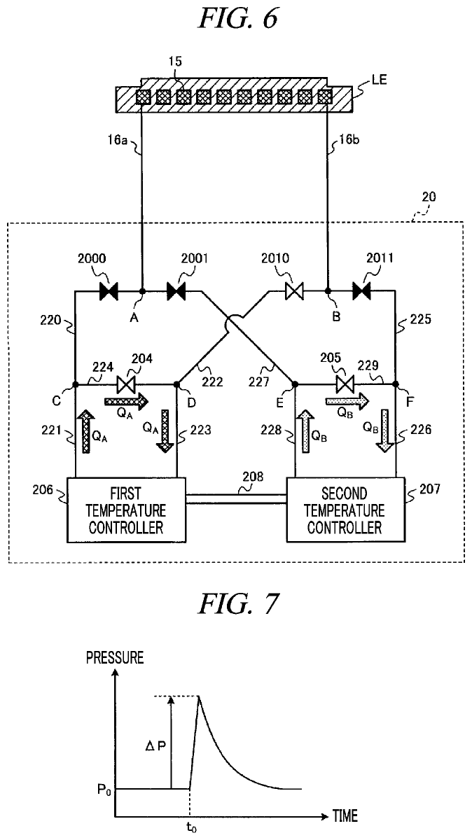

Referring to FIG. 3 again, at a time t₃, the control device 11 controls the first supply valve 2000 to close the first supply valve 2000. Accordingly, the temperature control device 20 becomes in a state, e.g., as illustrated in FIG. 6. FIG. 6 is a diagram illustrating an example of the temperature control device 20 when the first supply valve 2000 is closed. Since the first supply valve 2000 is closed, the first heat medium of the flow rate Q_{A} output from the first temperature controller 206 is returned to the first temperature controller 206 through the line 221, the line 224, the first bypass valve 204 and the line 223.

Herein, if the first bypass valve 204 is not opened and the first supply valve 2000 is closed, water hammer caused by the first heat medium of the flow rate Q_{A} is applied to the first supply valve 2000. FIG. 7 is a diagram illustrating an example of a variation in pressure applied to the first supply valve 2000 when the flow of the first heat medium is blocked. In FIG. 7, a pressure P₀ refers to a pressure within the first supply valve 2000 when the first supply valve 2000 is opened and the first heat medium flows.

If the first supply valve 2000 is closed at a time t₀ in a state where the first heat medium flows, the pressure applied to the first supply valve 2000 increases by ΔP. Depending on a magnitude of the pressure ΔP, the pressure ΔP may be higher than a pressure resistance of the first supply valve 2000 or a connection portion between the line 220 and the first supply valve 2000, and, thus, the first supply valve 2000 may be broken or the heat medium may leak out of the line 220.

To suppress the breakage of the first supply valve 2000 or the leakage of the heat medium, an increase in the pressure ΔP needs to satisfy the following Equation (1).

[Equation 1]

P₁>P₀ΔP (1)

In Equation (1), a pressure P₁ is a structural pressure resistance (allowable upper limit) of a path through which the heat medium flows. For example, the pressure P₁ is a lower one of a pressure resistance of the first supply valve 2000 and a pressure resistance of the connection portion between the line 220 and the first supply valve 2000.

Herein, the increase in the pressure ΔP caused by the water hammer can be represented by the following Equation (2).

$$\begin{matrix}[ Equation 2 ] & \\ \begin{matrix}Δ P = ρ \times a \times u \\ = ρ \times a \times Q \text{/} S\end{matrix} & ( 2 )\end{matrix}$$

In Equation (2), p is the density of the heat medium, a is the velocity of sound, u is the flow velocity of the heat medium and S is a cross-sectional area of the flow path for the heat medium.

Besides Equations (1) and (2), a flow rate Q of the first heat medium at the time of closing the first supply valve 2000 needs to satisfy the relationship of the following Equation (3) to suppress the breakage of the first supply valve 2000 or the leakage of the heat medium.

[Equation 3]

Q<(P₁−P₀)×S/ρ×a (3)

In the present exemplary embodiment, the conductance of the flow path including the line 220 and the conductance of the flow path including the line 224 are previously adjusted in order for the flow rate Q_{A1} of the first heat medium to satisfy the relationship of Equation (3) at the time of closing the first supply valve 2000. Further, before the first supply valve 2000 is closed, the first bypass valve 204 is opened, and, thus, the flow rate of the first heat medium flowing in the first supply valve 2000 decreases from Q_{A} to Q_{A1}. Accordingly, it is possible to suppress the breakage of the first supply valve 2000 or the leakage of the first heat medium when the first supply valve 2000 is closed.

Further, desirably, the time t₃ of closing the first supply valve 2000 may come after a time period required from the time t₂ of opening the first bypass valve 204 until the first heat medium flowing in the first supply valve 2000 is stabilized to the flow rate Q_{A1}.

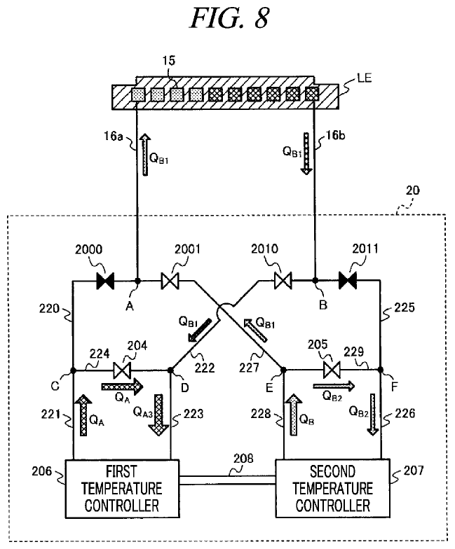

Then, referring to FIG. 3 again, at a time t₄, the control device 11 controls the second supply valve 2001 to open the second supply valve 2001. Accordingly, the temperature control device 20 becomes in a state, e.g., as illustrated in FIG. 8. FIG. 8 is a diagram illustrating an example of the temperature control device 20 when the second supply valve 2001 is opened.

Since the second supply valve 2001 is opened, the second heat medium of the flow rate Q_{B} output from the second temperature controller 207 is divided into the line 227 and the line 229 at the connection position E, and the second heat medium of a flow rate Q_{B2} flows in the line 229. Accordingly, the second heat medium of a flow rate Q_{B1}, which is the result of subtracting the flow rate Q_{B2} from the flow rate Q_{B}, flows in the line 227. Thus, the second heat medium of the flow rate Q_{B1} is supplied into the flow path 15 of the lower electrode LE.

The heat medium of the flow rate Q_{B1} is discharged from the flow path 15 according to the second heat medium of the flow rate Q_{B1} supplied into the flow path 15 of the lower electrode LE. Further, the discharged heat medium of the flow rate Q_{B1} passes through the line 16b, the first return valve 2010 and the line 222 and joins the first heat medium of the flow rate Q_{A} flowing in the line 224 at the connection position D to become the heat medium of a flow rate Q_{A3}. The heat medium of the flow rate Q_{A3} is returned to the first temperature controller 206. The flow rate Q_{A3} is higher than the flow rate Q_{A} output from the first temperature controller 206, and, thus, the liquid surface in the tank that stores the first heat medium within the first temperature controller 206 is raised. However, the tank that stores the first heat medium within the first temperature controller 206 and the tank that stores the second heat medium within the second temperature controller 207 are connected to each other via the line 208. Therefore, the leakage of the heat medium does not occur.

Further, a time t₄ of opening the second supply valve 2001 may be any time after the time t₃ of closing the first supply valve 2000 either simultaneously or sequentially. Accordingly, both the first supply valve 2000 and the second supply valve 2001 are opened. Thus, it is possible to suppress an excessive increase in the pressure of the heat medium within the line 16a, the flow path 15 and the line 16b.

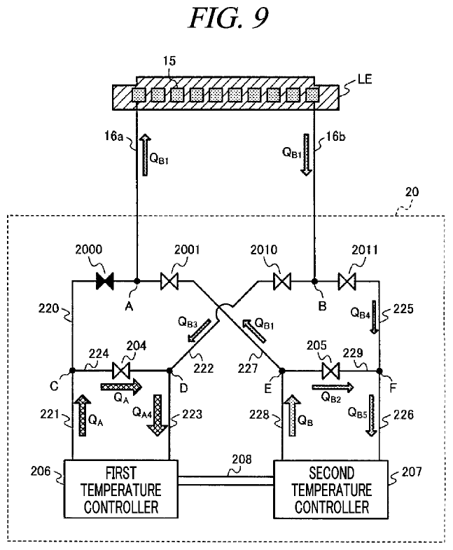

Then, referring to referring to FIG. 3 again, at a time t₅, the control device 11 controls the second return valve 2011 to open the second return valve 2011. Accordingly, the temperature control device 20 becomes in a state, e.g., as illustrated in FIG. 9. FIG. 9 is a diagram illustrating an example of the temperature control device 20 when the second return valve 2011 is opened.

Since the second return valve 2011 is opened, the heat medium of the flow rate Q_{B1} discharged from the inside of the flow path 15 of the lower electrode LE to the line 16b is divided into the line 222 and the line 225 at the connection position B, and the heat medium of a flow rate Q_{B3} flows in the line 222. The heat medium of the flow rate Q_{B3} joins the first heat medium of the flow rate Q_{A} flowing in the line 224 at the connection position D to become the heat medium of a flow rate Q_{A4}. The heat medium of the flow rate Qₐ₄ is returned to the first temperature controller 206.

Meanwhile, the heat medium of a flow rate Q_{B4}, which is the result of subtracting the flow rate Q_{B3} from the flow rate Q_{B1}, flows in the line 225. Thus, the heat medium of the flow rate Q_{B4} joins the second heat medium of the flow rate Q_{B2} flowing in the line 229 at the connection position F to become the heat medium of a flow rate Q_{B5}. The heat medium of the flow rate Q_{B5} is returned to the second temperature controller 207.

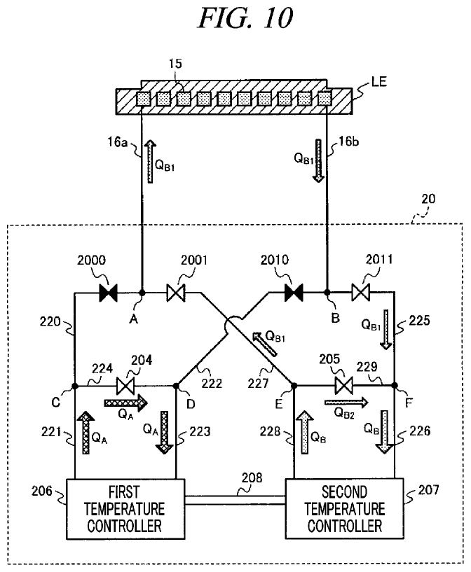

Then, referring to referring to FIG. 3 again, at a time t₆, the control device 11 controls the first return valve 2010 to close the first return valve 2010. Accordingly, the temperature control device 20 becomes in a state, e.g., as illustrated in FIG. 10. FIG. 10 is a diagram illustrating an example of the temperature control device 20 when the first return valve 2010 is closed.

Since the first return valve 2010 is closed, the heat medium of the flow rate Q_{B1} discharged from the inside of the flow path 15 of the lower electrode LE to the line 16b flows in the line 225 at the connection position B. Further, the heat medium of the flow rate Q_{B1} joins the second heat medium of the flow rate Q_{B2} flowing in the line 229 at the connection position F to become the heat medium of the flow rate Q_{B}. The heat medium of the flow rate Q_{B} is returned to the second temperature controller 207.

In the present exemplary embodiment, before the first return valve 2010 is closed, the second bypass valve 205 and the second return valve 2011 are opened, and, thus, the flow rate of the heat medium flowing in the first return valve 2010 decreases to Q_{B3} (see FIG. 9). In the present exemplary embodiment, the conductance of a flow path including the line 222 and the conductance of a flow path including the line 225 are previously adjusted in order for the flow rate Q_{B3} of the heat medium to satisfy Equation (3). Accordingly, it is possible to suppress the water hammer applied to the first return valve 2010 when the first return valve 2010 is closed. Therefore, it is possible to suppress the breakage of the first return valve 2010 or the leakage of the heat medium.

Further, desirably, the time t₆ of closing the first return valve 2010 may come after a time period required from the time t₅ of opening the second return valve 2011 until the flow rate of the heat medium flowing in the first return valve 2010 is stabilized. However, if the flow rate Q_{B1} of the heat medium discharged from the inside of the flow path 15 of the lower electrode LE to the line 16b satisfies Equation (3) with respect to the first return valve 2010, the time t₆ may be simultaneous with the time t₅. Further, if the flow rate Q_{B1} of the heat medium is low enough and the pressure of the heat medium within the line 16a, the flow path 15 and the line 16b does not increase that much even when the first return valve 2010 is closed, the second return valve 2011 may be opened after the first return valve 2010 is closed.

Furthermore, at the time t₄, the flow path 15 of the lower electrode LE is filled with the first heat medium right after the second supply valve 2001 is opened. For this reason, the first heat medium remaining within the flow path 15 of the lower electrode LE is discharged through the line 16b for some time after the second supply valve 2001 is opened. Therefore, if a time period from the time t₄ to the time t₅ is short, the first heat medium remaining within the flow path 15 of the lower electrode LE is returned to the tank of the second temperature controller 207. If the first heat medium is returned to the second temperature controller 207, the temperature of the heat medium in the tank of the second temperature controller 207 increases. Accordingly, to maintain the temperature of the heat medium in the tank at the second temperature, power consumption of the second temperature controller 207 increases.

Moreover, after the second supply valve 2001 is opened, the heat medium flowing in the first return valve 2010 is the first heat medium during a time period until the second heat medium passing through the second supply valve 2001 reaches the first return valve 2010 through the flow path 15 of the lower electrode LE and the line 16b. For this reason, desirably, the heat medium discharged from the inside of the flow path 15 of the lower electrode LE may be returned to the first temperature controller 206 during a time period from the opening of the second supply valve 2001 until the second heat medium passing through the second supply valve 2001 reaches the first return valve 2010.

Therefore, desirably, the second return valve 2011 may be closed and the first return valve 2010 may be opened during a time period from the time t₄ until the second heat medium passing through the second supply valve 2001 reaches the first return valve 2010. That is, desirably, the second return valve 2011 may be opened after a time period required from the opening of the second supply valve 2001 until the second heat medium passing through the second supply valve 2001 reaches the first return valve 2010. Accordingly, it is possible to suppress the supply of the heat medium of high temperature into the second temperature controller 207. Therefore, it is possible to suppress an increase in the power consumption of the second temperature controller 207. The time period required from the time t₄ of opening the second supply valve 2001 until the second heat medium flowing in the second supply valve 2001 reaches the first return valve 2010 through the flow path 15 of the lower electrode LE and the line 16b is an example of a predetermined time period.

Further, for example, if the second heat medium is supplied into the flow path 15 of the lower electrode LE before the state illustrated in FIG. 4, the second heat medium remains in the line 227 between the connection position E and the second supply valve 2001. In the state illustrated in FIG. 4, the second heat medium remaining in the line 227 is not returned to the second temperature controller 207. For this reason, if the state illustrated in FIG. 4 continues, the temperature of the second heat medium remaining in the line 227 may increase to the temperature (e.g., room temperature) of the inside of the temperature control device 20.

Furthermore, referring to FIG. 8, the temperature of the lower electrode LE is the first temperature right after the second supply valve 2001 is opened. Thus, even if the second heat medium is supplied into the flow path 15 of the lower electrode LE, the second heat medium is heated by the lower electrode LE. For this reason, for some time after the second supply valve 2001 is opened, the temperature of the heat medium discharged from the flow path 15 of the lower electrode LE becomes higher than that of the second heat medium.

Particularly, right after the second supply valve 2001 is opened, the heat medium remaining in the line 227 is supplied into the flow path 15 of the lower electrode LE. Thus, the temperature of the heat medium discharged from the flow path 15 of the lower electrode LE becomes much higher than that of the second heat medium. Therefore, desirably, at the time t₄, the second return valve 2011 stays closed and the first return valve 2010 stays opened during a time period from the opening of the second supply valve 2001 until the heat medium remaining in the line 227 passes through the first return valve 2010. Accordingly, the heat medium of higher temperature is returned to the first temperature controller 206. Therefore, it is possible to suppress the increase in the power consumption of the first temperature controller 206 and the second temperature controller 207.

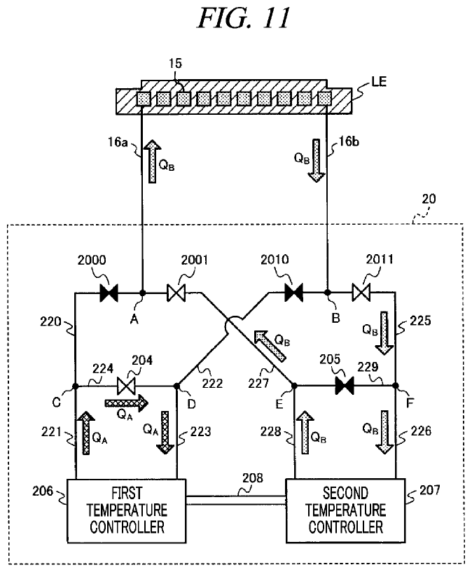

Then, referring to FIG. 3 again, at a time t₇, the control device 11 controls the second bypass valve 205 to close the second bypass valve 205. Accordingly, the temperature control device 20 becomes in a state, e.g., as illustrated in FIG. 11. FIG. 11 is a diagram illustrating an example of the temperature control device 20 when the second bypass valve 205 is closed.

Since the second bypass valve 205 is closed, all the second heat medium of the flow rate Q_{B} output from the second temperature controller 207 flows to the line 227 at the connection position E to be supplied into the flow path 15 of the lower electrode LE through the second supply valve 2001 and the line 16a. The second heat medium of the flow rate Q_{B} supplied into the flow path 15 of the lower electrode LE is returned to the second temperature controller 207 through the line 16b, the second return valve 2011, the line 225 and the line 226. Accordingly, the temperature of the lower electrode LE is switched from the first temperature to the second temperature.

In the present exemplary embodiment, when the second bypass valve 205 is closed, the heat medium of the flow rate Q_{B2} flows in the second bypass valve 205 (see FIG. 10). In the present exemplary embodiment, the conductance of the flow path including the line 227 and the conductance of the flow path including the line 229 are previously adjusted in order for the flow rate Q_{B3} of the heat medium to satisfy Equation (3). Accordingly, it is possible to suppress the water hammer applied to the second bypass valve 205 when the second bypass valve 205 is closed. Therefore, it is possible to suppress the breakage of the second bypass valve 205 or the leakage of the heat medium.

[Control Method of Heat Medium]

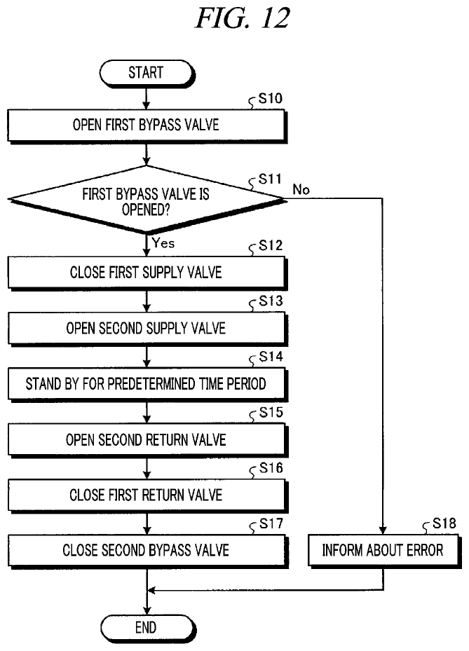

FIG. 12 is a flowchart showing an example of a control method of a heat medium according to the first exemplary embodiment of the present disclosure. The heat medium control method illustrated in FIG. 12 is implemented by controlling the components of the apparatus main body 10 mainly with the control device 11. For example, when the control device 11 detects the switchover from the first heat medium flowing in the flow path 15 of the lower electrode LE to the second heat medium, the control device 11 starts the processings illustrated in FIG. 12.

The flowchart of FIG. 12 shows the order of the switchover from the first heat medium flowing in the flow path 15 of the lower electrode LE to the second heat medium in the state (see FIG. 4) where the first heat medium flows in the flow path 15 of the lower electrode LE. Also, the switchover from the second heat medium flowing in the flow path 15 of the lower electrode LE to the first heat medium is performed in the same order in the state where the second heat medium flows in the flow path 15 of the lower electrode LE.

First, the control device 11 controls the first bypass valve 204 to open the first bypass valve 204 (S10). When the first bypass valve 204 is opened, the flow rate of the first heat medium flowing in the first supply valve 2000 decreases. The process S10 is an example of a flow rate control process.

Then, the control device 11 determines whether the first bypass valve 204 is opened based on the measurement values of the pressure measured by the pressure gauge 210 and the pressure gauge 211 (S11). The process S11 is an example of a determination process. If it is determined that the first bypass valve 204 is closed (S11: No), the control device 11 informs the user of the plasma processing apparatus 1 about the error (S18) and ends the heat medium control method shown in the present flowchart.

If it is determined that the first bypass valve 204 is opened (S11: Yes), the control device 11 controls the first supply valve 2000 to close the first supply valve 2000 (S12). Accordingly, the supply of the first heat medium into the flow path 15 of the lower electrode LE is stopped. The process S12 is an example of a supply stop process. Then, the control device 11 controls the second supply valve 2001 to open the second supply valve 2001 (S13).

Then, the control device 11 stands by for a predetermined time period (S14). For example, the predetermined time period is a time period required from the opening of the second supply valve 2001 in the process S13 until the second heat medium passing through the second supply valve 2001 reaches the first return valve 2010 through the flow path 15 of the lower electrode LE and the line 16b.

Then, the control device 11 controls the second return valve 2011 to open the second return valve 2011 (S15). Then, the control device 11 controls the first return valve 2010 to close the first return valve 2010 (S16). Thereafter, the control device 11 controls the second bypass valve 205 to close the second bypass valve 205 (S17). Then, the control device 11 ends the heat medium control method shown in the present flowchart. The processes S12, S13, S15 and S16 are an example of a switchover process.

The first exemplary embodiment has been described above. As described above, the heat medium control method according to the present exemplary embodiment includes the flow rate control process and the supply stop process. In the flow rate control process, the flow rate of the heat medium is decreased while the heat medium is supplied into the flow path 15 of the lower electrode LE configured to exchange heat with the wafer W from the first temperature controller 206 configured to supply the temperature controlled heat medium. In the supply stop process, the supply of the heat medium into the flow path 15 of the lower electrode LE is stopped by controlling the first supply valve 2000 provided at the supply line that connects the first temperature controller 206 and the flow path 15 in the lower electrode LE. Accordingly, it is possible to suppress the water hammer associated with the stop of supply of the heat medium.

Further, in the flow rate control process according to the present exemplary embodiment, when the first bypass valve 204 provided at the line 224 is opened, the flow rate of the heat medium to be supplied into the flow path 15 of the lower electrode LE is decreased. The line 224 is provided between the supply line and the return line that connects the first temperature controller 206 and the flow path 15 in the lower electrode LE and returns the heat medium, which is supplied through the supply line into the flow path 15 in the lower electrode LE, to the first temperature controller 206. Accordingly, it is possible to suppress the water hammer associated with the stop of supply of the heat medium.

Further, the heat medium control method according to the present exemplary embodiment further includes the determination process of determining whether the first bypass valve 204 is opened by using the pressure gauge 210 and the pressure gauge 211. The supply stop process is performed after the opening of the first bypass valve 204 is detected in the determination process. Accordingly, it is possible to suppress the water hammer associated with the stop of supply of the heat medium.

Furthermore, the present exemplary embodiment relates to the heat medium control method in the heat medium control apparatus, and the heat medium control method includes the flow rate control process and the supply stop process. The heat medium control apparatus includes the first supply line, the first return line, the second supply line, the second return line, the first switch unit 200 and the second switch unit 201. The first supply line is configured to supply the first heat medium into the flow path 15 formed in the lower electrode LE configured to exchange the heat with the wafer W from the first temperature controller 206 configured to supply the first heat medium serving as a fluid whose temperature is controlled to the first temperature. The first return line is configured to return the heat medium flowing in the flow path 15 of the lower electrode LE to the first temperature controller 206. The second supply line is connected to the first supply line and configured to supply the second heat medium into the flow path 15 formed in the lower electrode LE from the second temperature controller 207 configured to supply the second heat medium serving as a fluid whose temperature is controlled to the second temperature different from the first temperature. The second return line is connected to the first return line and configured to return the heat medium flowing in the flow path 15 of the lower electrode LE to the second temperature controller 207. The first switch unit 200 is provided at the connection portion between the first supply line and the second supply line and switches the heat medium to be supplied into the flow path 15 of the lower electrode LE to the first heat medium or the second heat medium. The second switch unit 201 is provided at the connection portion between the first return line and the second return line and switches the destination of the heat medium flowing out of the flow path 15 of the lower electrode LE to the first temperature controller 206 or the second temperature controller 207. Further, in the flow rate control process, the flow rate of the first heat medium is decreased while the first heat medium is supplied into the flow path 15 of the lower electrode LE from the first temperature controller 206. In the switchover process, the heat medium flowing in the flow path 15 of the lower electrode LE is switched from the first heat medium to the second heat medium by the first switch unit 200 and the second switch unit 201. Accordingly, it is possible to suppress the water hammer associated with the switch of the heat medium.

Moreover, in the above-described exemplary embodiment, the heat medium control apparatus further includes the line 224 and the first bypass valve 204. The line 224 is configured to connect the first supply line near the first temperature controller 206 rather than the connection portion between the first supply line and the second supply line and the first return line near the first temperature controller 206 rather than the connection portion between the first return line and the second return line. The first bypass valve 204 is provided at the line 224. Also, in the flow rate control process, when the first bypass valve 204 is opened, the flow rate of the first heat medium to be supplied into the flow path 15 of the lower electrode LE is decreased. Accordingly, it is possible to suppress the water hammer associated with the switch of the heat medium.

Further, the heat medium control method according to the above-described exemplary embodiment further includes the determination process of determining whether the first bypass valve 204 is opened by using the measurement values from the pressure gauge 210 and the pressure gauge 211. The switchover process is performed after the opening of the first bypass valve 204 is detected in the determination process. Accordingly, it is possible to suppress the water hammer associated with the switch of the heat medium.

Furthermore, in the above-described exemplary embodiment, the first switch unit 200 includes the first supply valve 2000 and the second supply valve 2001. The first supply valve 2000 is configured as the two-way valve and provided at the first supply line near the first temperature controller 206 rather than the connection position between the first supply line and the second supply line. The second supply valve 2001 is configured as the two-way valve and provided at the second supply line near the second temperature controller 207 rather than the connection position between the first supply line and the second supply line. Also, in the switchover process, the second supply valve 2001 is opened after the first supply valve 2000 is closed. Accordingly, it is possible to suppress the leakage of the heat medium.

Moreover, in the above-described exemplary embodiment, the second switch unit 201 includes the first return valve 2010 and the second return valve 2011. The first return valve 2010 is configured as the two-way valve and provided at the first return line near the first temperature controller 206 rather than the connection position between the first return line and the second return line. The second return valve 2011 is configured as the two-way valve and provided at the second return line near the second temperature controller 207 rather than the connection position between the first return line and the second return line. Also, in the switchover process, the second return valve 2011 is opened and the first return valve 2010 is closed after a predetermined time period from the opening of the second supply valve 2001. Accordingly, it is possible to suppress the increase in the power consumption of the first temperature controller 206 and the second temperature controller 207.

Further, in the above-described exemplary embodiment, the predetermined time period is equal to or larger than a time period required until the second heat medium from the second supply valve 2001 passes through the flow path 15 of the lower electrode LE and reaches the first return valve 2010. Accordingly, it is possible to suppress the increase in the power consumption of the first temperature controller 206 and the second temperature controller 207.

Furthermore, the heat medium control apparatus according to the above-described exemplary embodiment includes the first supply line, the first return line, the second supply line, the second return line, the first switch unit 200, the second switch unit 201 and the control device 11. The first supply line is configured to supply the first heat medium into the flow path 15 formed in the lower electrode LE configured to exchange the heat with the wafer W from the first temperature controller 206 configured to supply the first heat medium serving as the fluid whose temperature is controlled to the first temperature. The first return line is configured to return the heat medium flowing in the flow path 15 of the lower electrode LE to the first temperature controller 206. The second supply line is connected to the first supply line and configured to supply the second heat medium into the flow path 15 formed in the lower electrode LE from the second temperature controller 207 configured to supply the second heat medium serving as the fluid whose temperature is controlled to the second temperature different from the first temperature. The second return line is connected to the first return line and configured to return the heat medium flowing in the flow path 15 of the lower electrode LE to the second temperature controller 207. The first switch unit 200 is provided at the connection portion between the first supply line and the second supply line and switches the heat medium to be supplied into the flow path 15 of the lower electrode LE to the first heat medium or the second heat medium. The second switch unit 201 is provided at the connection portion between the first return line and the second return line and switches the destination of the heat medium flowing out of the flow path 15 of the lower electrode LE to the first temperature controller 206 or the second temperature controller 207. The control device 11 performs a processing of decreasing the flow rate of the first heat medium while the first heat medium is supplied from the first temperature controller 206 into the flow path 15 of the lower electrode LE and then controls the first switch unit 200 and the second switch unit 201 to switch the heat medium flowing in the flow path 15 of the lower electrode LE from the first heat medium to the second heat medium. Accordingly, it is possible to suppress the water hammer associated with the switch of the heat medium.

### Second Exemplary Embodiment

In the first exemplary embodiment, the flow rate of the first heat medium flowing in the first supply valve 2000 is decreased by opening the first bypass valve 204 before closing the first supply valve 2000. In the present exemplary embodiment, the flow rate of the heat medium output from the first temperature controller 206 is decreased by controlling the first temperature controller 206 before starting a switchover of the heat medium.

[Operation of Temperature Control Device 20]

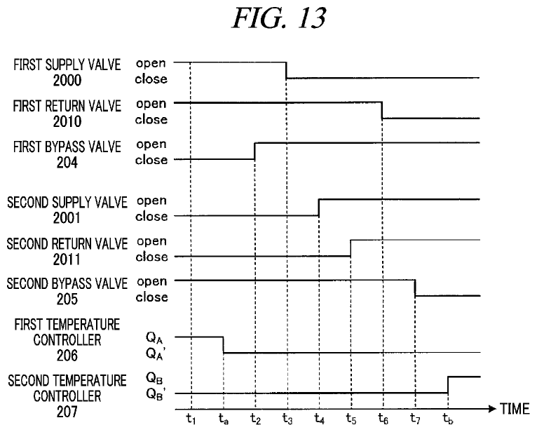

FIG. 13 is a timing chart showing an example of an operation of the temperature control device 20 according to a second exemplary embodiment of the present disclosure. The timing chart of FIG. 13 shows an operation of the temperature control device 20 in which the first heat medium flowing in the flow path 15 of the lower electrode LE is switched to the second heat medium in a state (initial state) where the first heat medium flows in the flow path 15 of the lower electrode LE. The temperature control device 20 in the initial state is, e.g., as illustrated in FIG. 4. However, the flow rate of the second heat medium output from the second temperature controller 207 is set to a flow rate Q_{B′} that is lower than the flow rate Q_{B}. Also, a switchover from the second heat medium flowing in the flow path 15 of the lower electrode LE to the first heat medium is performed in the same order in the state where the second heat medium flows in the flow path 15 of the lower electrode LE.

First, at a time t₁, the control device 11 detects a switchover from the first heat medium flowing in the flow path 15 of the lower electrode LE to the second heat medium. Then, at a time tₐ, the control device 11 controls the first temperature controller 206 to decrease the flow rate Q_{A} of the first heat medium output from the first temperature controller 206 to a flow rate Q_{A′}, that is lower than the flow rate Q_{A}. The process of decreasing the flow rate Q_{A} of the first heat medium output from the first temperature controller 206 to the flow rate Q_{A′}, is included in an example of the flow rate control process.

Then, at a time t₂, the control device 11 opens the first bypass valve 204. Then, the control device 11 closes the first supply valve 2000 at a time t₃ and opens the second supply valve 2001 at a time t₄. Thereafter, the control device 11 opens the second return valve 2011 at a time t₅ after a predetermined time period from the time t₄ of opening the second supply valve 2001 and closes the first return valve 2010 at a time t₆. Accordingly, the first heat medium output from the first temperature controller 206 circulates at the flow rate Q_{A′} through the line 221, the line 224 and the line 223. Accordingly, it is possible to reduce an output of a pump within the first temperature controller 206. Therefore, it is possible to reduce the power consumption of the first temperature controller 206.

Then, the control device 11 closes the second bypass valve 205 at a time t₇. Thereafter, at a time t_{b}, the control device 11 controls the second temperature controller 207 to increase the flow rate Q_{B′} of the second heat medium output from the second temperature controller 207 to the flow rate Q_{B}. Accordingly, the temperature control device 20 becomes in the state, e.g., as illustrated in FIG. 11. Herein, the flow rate of the first heat medium output from the first temperature controller 206 is Q_{A′}.

The second exemplary embodiment has been described above. As described above, in the flow rate control process in the heat medium control method according to the present exemplary embodiment, the flow rate of the heat medium to be supplied into the flow path 15 of the lower electrode LE is deceased by decreasing the flow rate of the heat medium output from the first temperature controller 206. Accordingly, it is possible to reduce the power consumption of the first temperature controller 206.

### Third Exemplary Embodiment

In the first exemplary embodiment, the first switch unit 200 is implemented by the first supply valve 2000 and the second supply valve 2001 that are the two-way valves, and the second switch unit 201 is implemented by the first return valve 2010 and the second return valve 2011 that are the two-way valves. However, in the present exemplary embodiment, each of the first switch unit 200 and the second switch unit 201 is implemented by a three-way valve. Hereinafter, descriptions will be made focusing on a difference from the first exemplary embodiment.

[Configuration of Temperature Control Device 20]

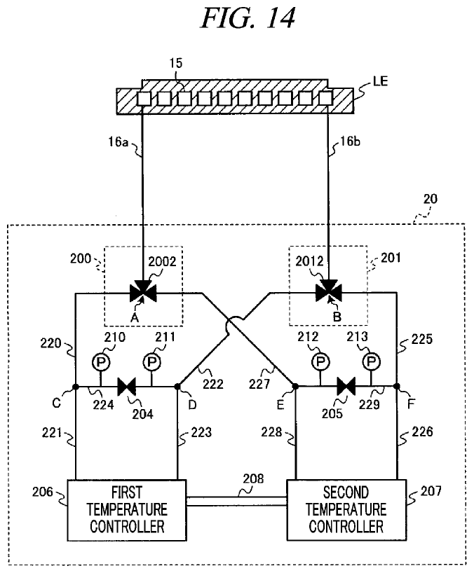

FIG. 14 is a diagram illustrating an example of a temperature control device 20 according to a third exemplary embodiment of the present disclosure. Further, in FIG. 14, since parts assigned same reference numerals as those of FIG. 2 have the same configuration or functions as those of FIG. 2 except for the following, detailed description thereof will be omitted. In the present exemplary embodiment, the first switch unit 200 is implemented by a supply valve 2002 that is a three-way valve, and the second switch unit 201 is implemented by a return valve 2012 that is a three-way valve.

As for the three-way valve, when the first heat medium flowing in the flow path 15 of the lower electrode LE is switched to the second heat medium, a valve for the first heat medium is closed, and, thus, water hammer is applied to the corresponding valve. For this reason, in the present exemplary embodiment, a flow rate of the first heat medium flowing in the three-way valve is decreased by opening the first bypass valve 204 before closing the valve for the first heat medium. Accordingly, it is possible to suppress the water hammer associated with the switch of the heat medium. The same applies to a switchover from the second heat medium flowing in the flow path 15 of the lower electrode LE to the first heat medium.

[Control Method of Heat Medium]

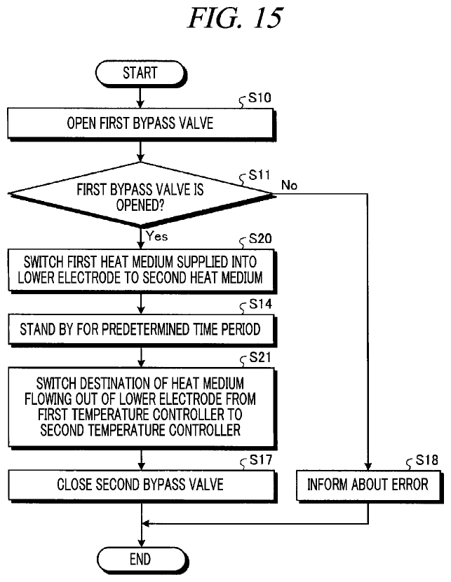

FIG. 15 is a flowchart showing an example of a control method of a heat medium according to the third exemplary embodiment of the present disclosure. The heat medium control method illustrated in FIG. 15 is implemented by controlling the components of the apparatus main body 10 mainly with the control device 11. For example, when the control device 11 detects a switchover from the first heat medium flowing in the flow path 15 of the lower electrode LE to the second heat medium, the control device 11 starts the processings illustrated in FIG. 15.

The flowchart of FIG. 15 shows the order of a switchover from the first heat medium flowing in the flow path 15 of the lower electrode LE to the second heat medium in the state where the first heat medium flows in the flow path 15 of the lower electrode LE. Also, a switchover from the second heat medium flowing in the flow path 15 of the lower electrode LE to the first heat medium is performed in the same order in the state where the second heat medium flows in the flow path 15 of the lower electrode LE.

First, the control device 11 controls the first bypass valve 204 to open the first bypass valve 204 (S10). Then, the control device 11 determines whether the first bypass valve 204 is opened based on measurement values of the pressure measured by the pressure gauge 210 and the pressure gauge 211 (S11). If it is determined that the first bypass valve 204 is not opened (S11: No), the control device 11 informs the user of the plasma processing apparatus 1 about an error (S18) and ends the heat medium control method shown in the present flowchart.

If it is determined that the first bypass valve 204 is opened (S11: Yes), the control device 11 controls the supply valve 2002 to switch the first heat medium to be supplied into the flow path 15 of the lower electrode LE to the second heat medium (S20).

Then, the control device 11 stands by for a predetermined time period (S14). For example, the predetermined time period in the process S14 of the present exemplary embodiment is a time period required from the switchover from the first heat medium to be supplied into the flow path 15 of the lower electrode LE to the second heat medium by the supply valve 2002 in the process S20 until the second heat medium passing through the supply valve 2002 reaches the return valve 2012 through the flow path 15 of the lower electrode LE and the line 16b.

Then, the control device 11 controls the return valve 2012 to switch the destination of the heat medium flowing out of the flow path 15 of the lower electrode LE from the first temperature controller 206 to the second temperature controller 207 (S21). Thereafter, the control device 11 closes the second bypass valve 205 (S17). Then, the control device 11 ends the heat medium control method shown in the present flowchart.

The third exemplary embodiment has been described above. Even in the present exemplary embodiment, it is possible to suppress the water hammer associated with the switch of the heat medium.

[Others]

Herein, the above-described exemplary embodiments are not limiting, and various changes and modifications may be made without departing from the scope of the present disclosure.

For example, in the above-described second exemplary embodiment, the flow rate of the heat medium output from the first temperature controller 206 is decreased before the first supply valve 2000 is closed, and, thus, the first bypass valve 204 is opened. Accordingly, before the first supply valve 2000 is closed, the flow rate of the first heat medium flowing in the first supply valve 2000 is decreased. However, the present disclosure is not limited thereto. For example, if the flow rate of the heat medium output from the first temperature controller 206 can be decreased to the flow rate that satisfies Equation (3) before the first supply valve 2000 is closed, the first bypass valve 204 may not be opened. In this case, the line 224 and the first bypass valve 204 may not be provided within the temperature control device 20. The same applies to the line 229 and the second bypass valve 205.

Further, in each of the above-described exemplary embodiments, the temperature of the lower electrode LE is controlled by switching between the first heat medium and the second heat medium different from each other in the temperature. However, the present disclosure is not limited thereto. For example, the technical concept of decreasing the flow rate of the heat medium before stopping the supply of the heat medium can be applied to an apparatus configured to control the temperature of the lower electrode LE with one kind of heat medium.

Furthermore, in each of the above-described exemplary embodiments, the heat medium has been described as the fluid of which supply is performed and stopped repeatedly. However, the present disclosure is not limited thereto, but can be applied to controlling a fluid of which supply is performed and stopped repeatedly.

Moreover, the above-described second exemplary embodiment and third exemplary embodiment can be combined with each other. That is, the flow rate of the heat medium output from the first temperature controller 206 may be decreased by controlling the first temperature controller 206 before the first heat medium flowing in the flow path 15 of the lower electrode LE is switched to the second heat medium by the supply valve 2002.

Further, in the above-described exemplary embodiments, capacitively coupled plasm (CCP) is used as a plasma source. However, the technology of the present disclosure is not limited thereto. For example, inductively coupled plasma (ICP), microwave-excited surface wave plasma (SWP), electron cyclotron resonance plasma (ECP), or helicon wave-excited plasma (HWP) may be used as the plasma source.

Furthermore, in the above-described exemplary embodiments, the plasma etching apparatus has been described as the plasma processing apparatus 1. However, the technology of the present disclosure is not limited thereto. The technology of the present disclosure can be applied to a film forming apparatus, a modifying apparatus, or a cleaning apparatus in addition to the etching apparatus as long as the apparatus is capable of controlling the temperature of a temperature control target object such as a wafer W by using a heat medium with controlled temperature.

According to the exemplary embodiments, it is possible to suppress the water hammer associated with the stop of the supply of the heat medium.

The exemplary embodiments disclosed herein are illustrative in all aspects and not limited thereto. In fact, the above exemplary embodiments can be embodied in various forms. Further, the above-described exemplary embodiments may be omitted, substituted, or changed in various forms without departing from the scope of the appended claims.

From the foregoing, it will be appreciated that various exemplary embodiments of the present disclosure have been described herein for the purposes of illustration, and that various modifications may be made without departing from the scope and spirit of the present disclosure. Accordingly, the various exemplary embodiments disclosed herein are not intended to be limiting, with the true scope and spirit being indicated by the following claims.

We claim:

1. A control method of a heat medium, comprising:
decreasing a flow rate of the heat medium in a state where the heat medium is being supplied from a temperature controller configured to supply the heat medium whose temperature is controlled into a flow path formed in a heat exchange member configured to exchange heat with a temperature control target object; and
stopping a supply of the heat medium into the flow path by controlling a supply valve provided at a supply line that connects the temperature controller and the flow path of the heat exchange member.

2. The control method of the heat medium of claim 1,
wherein, in the decreasing of the flow rate,
the flow rate of the heat medium supplied into the flow path is decreased by opening a bypass valve provided at a bypass line provided between the supply line and a return line that connects the temperature controller and the flow path of the heat exchange member and returns the heat medium, which is supplied through the supply line into the flow path of the heat exchange member, to the temperature controller.

3. The control method of the heat medium of claim 2, further comprising:
determining whether the bypass valve is opened by using a sensor configured to detect opening of the bypass valve,
wherein the stopping of the supply of the heat medium is performed after the opening of the bypass valve is detected in the determining whether the bypass valve is opened.

4. The control method of the heat medium of claim 1,
wherein, in the decreasing of the flow rate,
the flow rate of the heat medium supplied into the flow path is decreased by decreasing the flow rate of the heat medium output from the temperature controller.

5. A control method of a heat medium in a heat medium control apparatus including: a first supply line configured to supply a first heat medium from a first temperature controller configured to supply the first heat medium serving as a fluid whose temperature is controlled to a first temperature into a flow path formed in a heat exchange member configured to exchange heat with a temperature control target object; a first return line configured to return the heat medium flowing in the flow path to the first temperature controller; a second supply line connected to the first supply line and configured to supply a second heat medium from a second temperature controller configured to supply the second heat medium serving as a fluid whose temperature is controlled to a second temperature different from the first temperature into the flow path formed in the heat exchange member; a second return line connected to the first return line and configured to return the heat medium flowing in the flow path to the second temperature controller; a first switch unit provided at a connection portion between the first supply line and the second supply line and configured to switch the heat medium supplied into the flow path to the first heat medium or the second heat medium; and a second switch unit provided at a connection portion between the first return line and the second return line and configured to switch a destination of the heat medium flowing out of the flow path to the first temperature controller or the second temperature controller, the control method of the heat medium comprising:
decreasing a flow rate of the first heat medium in a state where the first heat medium is being supplied from the first temperature controller into the flow path; and
switching the heat medium flowing in the flow path from the first heat medium to the second heat medium by the first switch unit and the second switch unit.

6. The control method of the heat medium of claim 5,
wherein the heat medium control apparatus further includes:
a bypass line that connects the first supply line near the first temperature controller rather than the connection portion between the first supply line and the second supply line with the first return line near the first temperature controller rather than the connection portion between the first return line and the second return line; and
a bypass valve provided at the bypass line, and
wherein, in the decreasing of the flow rate,
the flow rate of the first heat medium supplied into the flow path is decreased by opening the bypass valve.

7. The control method of the heat medium of claim 6, further comprising:
determining whether the bypass valve is opened by using a sensor configured to detect opening of the bypass valve,
wherein the switching of the heat medium is performed after the opening of the bypass valve is detected in the determining whether the bypass valve is opened.

8. The control method of the heat medium of claim 5,
wherein, in the decreasing of the flow rate,
the flow rate of the first heat medium supplied into the flow path is decreased by decreasing the flow rate of the first heat medium output from the first temperature controller.

9. The control method of the heat medium of claim 5,
wherein the first switch unit includes:
a first supply valve configured as a two-way valve and provided at the first supply line near the first temperature controller rather than a connection position between the first supply line and the second supply line; and
a second supply valve configured as a two-way valve and provided at the second supply line near the second temperature controller rather than the connection position between the first supply line and the second supply line, and
wherein, in the switching of the heat medium,
the second supply valve is opened after a timing of closing the first supply valve.

10. The control method of the heat medium of claim 9,
wherein the second switch unit includes:
a first return valve configured as a two-way valve and provided at the first return line near the first temperature controller rather than a connection position between the first return line and the second return line; and
a second return valve configured as a two-way valve and provided at the second return line near the second temperature controller rather than the connection position between the first return line and the second return line, and
wherein, in the switching of the heat medium,
the second return valve is opened and the first return valve is closed at a timing when a predetermined time period is elapsed from a timing of opening the second supply valve.

11. The control method of the heat medium of claim 10,
wherein the predetermined time period is equal to or larger than a time period required until the second heat medium from the second supply valve flows through the flow path to reach the first return valve.

12. The control method of the heat medium of claim 5,
wherein, in the switching of the heat medium,
the second switch unit switches the destination of the heat medium flowing out of the flow path from the first temperature controller to the second temperature controller at a timing when a predetermined time period is elapsed from a timing of switching the heat medium supplied into the flow path from the first heat medium to the second heat medium by the first switch unit.

13. The control method of the heat medium of claim 12,
wherein the predetermined time period is equal to or larger than a time period required until the second heat medium from the first switch unit flows through the flow path to reach the second switch unit.

14. A heat medium control apparatus, comprising:
a first supply line configured to supply a first heat medium from a first temperature controller configured to supply the first heat medium serving as a fluid whose temperature is controlled to a first temperature into a flow path formed in a heat exchange member configured to exchange heat with a temperature control target object;
a first return line configured to return the heat medium flowing in the flow path to the first temperature controller;
a second supply line connected to the first supply line and configured to supply a second heat medium from a second temperature controller configured to supply the second heat medium serving as a fluid whose temperature is controlled to a second temperature different from the first temperature into the flow path formed in the heat exchange member;
a second return line connected to the first return line and configured to return the heat medium flowing in the flow path to the second temperature controller;
a first switch unit provided at a connection portion between the first supply line and the second supply line and configured to switch the heat medium supplied into the flow path to the first heat medium or the second heat medium;
a second switch unit provided at a connection portion between the first return line and the second return line and configured to switch a destination of the heat medium flowing out of the flow path to the first temperature controller or the second temperature controller; and
a controller configured to decrease a flow rate of the first heat medium in a state where the first heat medium is being supplied into the flow path from the first temperature controller and then control the first switch unit and the second switch unit to switch the heat medium flowing in the flow path from the first heat medium to the second heat medium.
